(19) United States
(12) Patent Application Publication
(10) Pub. No.: US 2007/0262444 A1
(43) Pub. Date: Nov. 15, 2007

(54) Semiconductor device and chip structure thereof

(75) Inventors: Yung-Chang Chen, Taichun (TW); Yuan-Lin Tzeng, Taichung (TW); Ming-Tsung Wang, Taichung (TW); Jeng-Yuan Lai, Taichung Hsien (TW); Cheng-Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/800,451

(22) Filed: May 4, 2007

(30) Foreign Application Priority Data
May 10, 2006 (TW) 095116525

(51) Int. Cl. H01L 23/34

(52) U.S. Cl. 257/712

(57) ABSTRACT

A semiconductor device, a chip structure thereof, and a method for fabricating the same are proposed. The method involves cutting a wafer with an array of chips twice so as to separate the chips and to form a chip structure. The first cutting is wider than the second cutting, and both are performed on an inactive surface of each of the chips. The chip structure includes a protruding portion formed on the inactive surface. The chip structure is electrically connected to a substrate by conductive bumps in a flip-chip manner and mounted with a heat sink. A decrease in contact area between the chip and the heat sink reduces warpage caused to the semiconductor device by thermal stress, thus preventing delamination of the heat sink and cracking of the conductive bumps, and reducing the expense and time spent on finding suitable underfill materials.

### FIELD OF THE INVENTION

The present invention relates to semiconductor devices and chip structures, and more particularly, to a flip-chip semiconductor device and a chip structure thereof.

### BACKGROUND OF THE INVENTION

In order to dissipate heat effectively, a heat sink may be employed in a semiconductor package. For example, a known flip-chip ball grid array (FCBGA) semiconductor package employs a heat sink mounted on a flip-chip semiconductor chip to efficiently dissipate the heat generated by the flip-chip semiconductor chip. Techniques related to aforesaid applications are briefly discussed herein; similar techniques may be found in U.S. Pat. Nos. 5,619,070 and 5,909,056.

FIG. 1 is a cross-sectional view of a prior flip-chip ball grid array semiconductor package fabricated with a heat sink. Referring to FIG. 1, a chip 11 having an active surface and an inactive surface is mounted on a substrate 10 via a plurality of conductive bumps 12, an underfill material 13 is formed among the conductive bumps 12, a heat sink 15 having a flat portion 150 and a supporting portion 151 extended from the flat portion 150 is mounted on a surface of the substrate 10 by means of an adhesive 14 applied to the supporting portion 151, wherein the chip 11 is disposed in an accommodating space defined by the flat portion 150 and the supporting portion 151, and the inactive surface of the chip 11 is attached to the flat portion 150 through a heat conductive adhesive layer 16, such that the heat generated by the chip 11 during operation may be dissipated by the heat sink 15.

However, as the coefficients of thermal expansion (CTE) of the heat sink and the chip are significantly different, thermal stress and thermal deformation arising during the thermal cycle of the semiconductor package often results in warpage of the semiconductor package, and may even cause the heat sink to detach from the semiconductor package and cause the conductive bumps to crack, thereby affecting the quality of electrical connection between the chip and the substrate.

In current practice, an underfill material having a low Young's modulus is employed to absorb the thermal stress so as to solve the problem of thermal stress generated due to different coefficients of thermal expansion (CTE). However, the underfill material with a low Young's modulus is unable to provide sufficient support for the conductive bumps of the flip-chip semiconductor chip. In other words, an underfill material with a high Young's modulus provides sufficient support for the conductive bumps, but the flip-chip semiconductor chip is easily subject to thermal stress and thereby suffers from problems such as delamination and cracking of the conductive bumps. This thereby makes only one kind of underfill material suitable for applying to a specific chip and a specific substrate. As a result, different kinds of underfill materials have to be acquired and tested before applying to various chips and substrates with different sizes and models. Nevertheless, finding suitable underfill materials for attaching chips of different sizes and models to a substrate is time-consuming, laborious and test-intensive, and could dramatically increase fabrication time and fabrication cost.

Accordingly, a need still remains for providing a semiconductor device and a chip structure thereof, which is capable of preventing delamination and any problem that may affect the electrical connection between the chip and the substrate, and reducing the time and expense spent on finding suitable underfill materials.

Solutions to these problems have been long sought but prior developments have not taught or suggested any solutions and, thus, solutions to these problems have long eluded those skilled in the art.

### SUMMARY OF THE INVENTION

In light of the above drawbacks of the prior art, a primary objective of the present invention is to provide a semiconductor device and a chip structure thereof, which can reduce thermal stress arising from a mismatch in thermal expansion coefficients between the chip and a heat sink.

Another objective of the present invention is to provide a semiconductor device and a chip structure thereof, which can ensure the quality of electrical connection between the chip and a substrate and prevent delamination of a heat sink.

Yet another objective of the present invention is to provide a semiconductor device and a chip structure thereof, which can reduce fabrication time and cost spent on finding suitable underfill materials, which are capable of attaching heat sinks of different kinds and chips of different sizes on a substrate.

In order to achieve the above and other objectives, the present invention discloses a chip structure and a method for fabricating the chip structure. The method for fabricating the chip structure comprises the steps of providing a wafer with an array of chips each having an active surface and an inactive surface opposing the active surface, forming grooves between the chips, and cutting the chips along the grooves so as to separate the chips from each other, thereby forming a protruding portion on the inactive surface of the chip. The grooves are grid-like and are each disposed on the inactive surface. The grooves are wider than cutting channels, which may be predetermined in the grooves and cut to separate the chips from each other.

According to the foregoing fabrication method, the chip structure comprises a body and a protruding portion, wherein the body comprises an active surface and an inactive surface opposing the active surface, and the protruding portion is formed on the inactive surface. In addition, the protruding portion to inactive surface ratio in terms of size is between 0.5 and 0.8, and is preferably 0.67.

Moreover, a semiconductor device disclosed in the present invention comprises a substrate, a chip, and a heat sink. The chip has an active surface and an inactive surface opposing the active surface, wherein a protruding portion is formed on the inactive surface, such that the chip is mounted on the substrate via a plurality of conductive bumps formed on the active surface. In addition, the heat sink comprises a flat portion and a supporting portion extended from the flat portion, and is mounted on the protruding portion of the inactive surface of the chip. Furthermore, the heat sink is disposed on a surface of the substrate via the supporting portion and by means of an adhesive, such that the chip is accommodated in a receiving space defined by the flat portion and the supporting portion. The protruding portion on the inactive surface of the chip is glued to the flat portion of the heat sink by a heat conductive adhesive layer, thus allowing the heat sink to effectively dissipate the heat generated by the chip during the operation.

Therefore, the present invention of fabricating the semiconductor device and the chip structure involves cutting a wafer with an array of chips twice, namely forming grid-like grooves between the chips during the first cutting, and separating the chips from each other by cutting the grooves along cutting channels between the chips during the second cutting. The first cutting is wider than the second cutting, thereby forming a chip structure with a protruding portion on the inactive surface. The chip structure is electrically connected to a substrate in a flip-chip manner, and mounted with a heat sink. The protruding portion to inactive surface ratio in terms of size is around 0.5 to 0.8, and is preferably 0.67. Minimizing contact area between the chip structure and the heat sink can reduce warpage of the semiconductor device by thermal stress, thereby preventing delamination of the heat sink and cracking of conductive bumps, as well as reducing the expense and time spent on finding suitable underfill materials.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

The present invention can be more fully understood by reading the following detailed description of the preferred embodiment, with reference made to the accompanying drawings, wherein:

FIG. 1 (PRIOR ART) is a cross-sectional view showing a known semiconductor package with a heat sink;

FIGS. 2A to 2E are schematic views showing a chip structure and the procedure steps of a method for fabricating the chip structure in accordance with one preferred embodiment of the present invention; and

FIG. 3 is a cross-sectional view showing a semiconductor device fabricated in accordance with one preferred embodiment of the present invention.

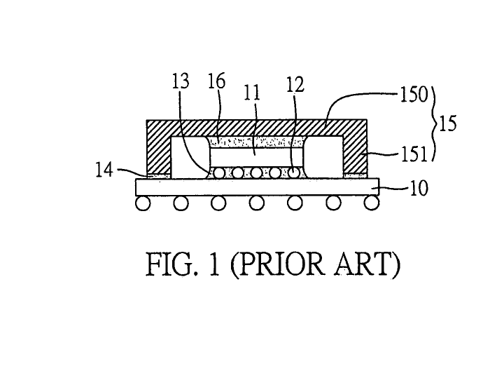

### DETAILED DESCRIPTION OF THE EMBODIMENT

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

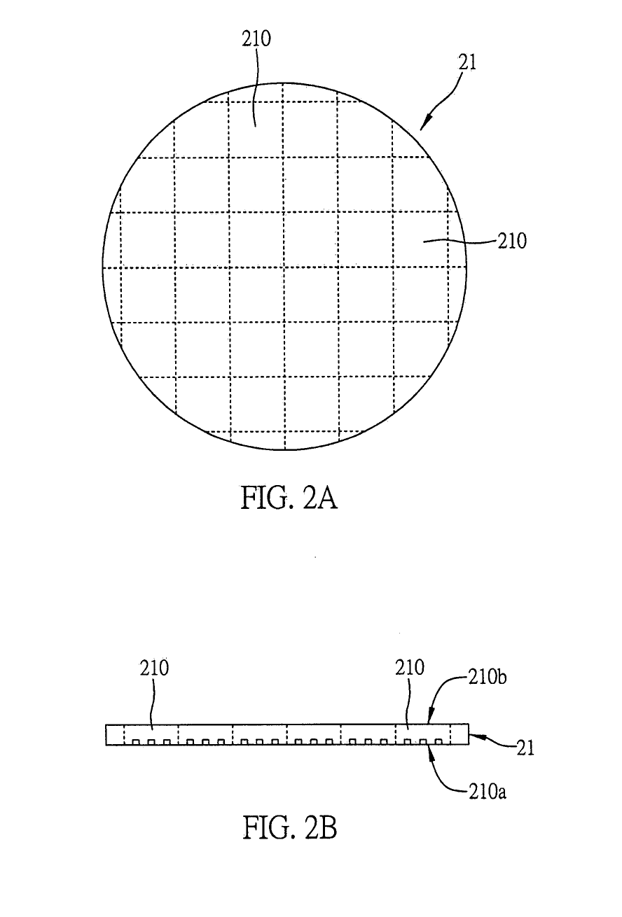

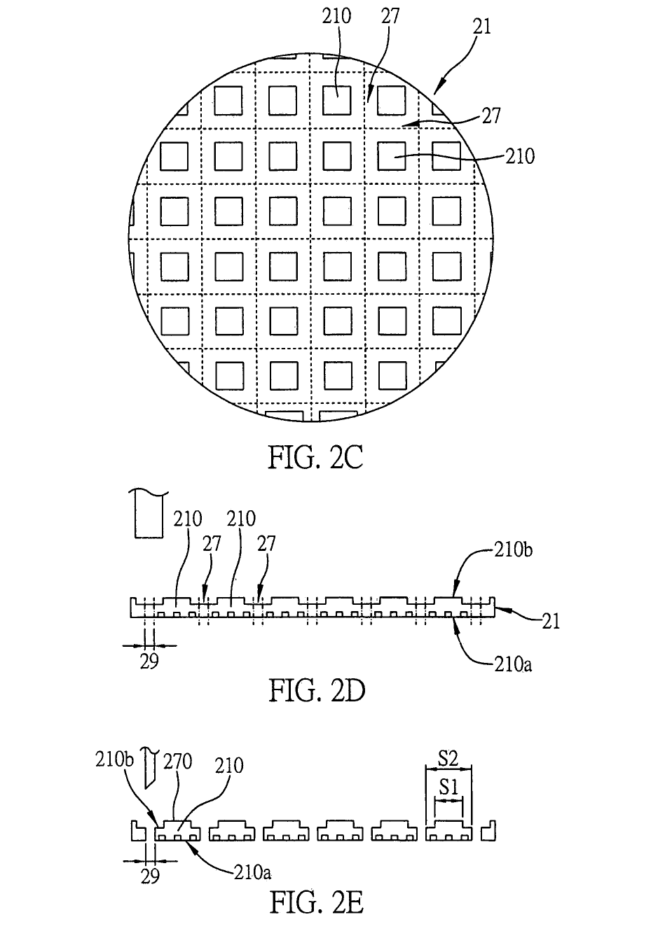

FIGS. 2A to 2E are schematic views showing a chip structure and the procedure steps of a method for fabricating the chip structure in accordance with one preferred embodiment of the present invention.

As shown in FIGS. 2A and 2B, wherein FIG. 2B is a cross-sectional view of FIG. 2A, a wafer 21 having an array of chips 210 is provided, and each of the chips 210 has an active surface 210a and an inactive surface 210b opposing the active surface 210a. Referring to FIGS. 2C and 2E, the drawings depict that two cutting procedures are performed, such that the wafer 21 is cut twice, wherein FIG. 2D is a cross-sectional view of FIG. 2C under a first cutting procedure and FIG. 2E is a cross-sectional view of FIG. 2C under a second cutting procedure.

First of all, a first cutting procedure is perform to cut the inactive surface 210b of each of the chips 210 by a grinder so as to form a plurality of grid-like grooves 27 between the chips 210 on the wafer 21.

Then, as shown in FIG. 2E, a second cutting procedure is performed to cut through the grooves 27 along a plurality of cutting channels 29 between the chips 210, in order to separate the chips 210 from each other. It should be noted that the cutting channels 29 may be predetermined in the grooves 27, and the grooves 27 are wider than the cutting channels 29. In other words, the first cutting is wider than the second cutting so as to form a protruding portion 270 on the inactive surface 210b of the chip 210. At this stage of fabrication, a chip structure having an inverted T-shaped cross-section is formed. Furthermore, the ratio of the size S1 of the protruding portion 270 to the size S2 of the inactive surface 210b is about 0.5 to 0.8, and is preferably 0.67.

Accordingly, after performing the preceding fabrication procedures, the chip structure comprises a body with an active surface 210a and an inactive surface 210b opposing the active surface 21 0a, and a protruding portion 270 formed on the inactive surface 210b.

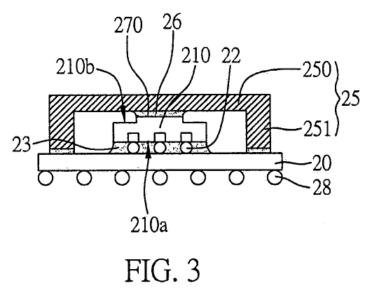

Referring to FIG. 3, a packaging process is subsequently preformed on the forgoing chip structure so as to fabricate a semiconductor device in accordance with one preferred embodiment of the present invention

Moreover, as shown in FIG. 3, the semiconductor device comprises a substrate 20, a chip 210, and a heat sink 25. The chip 210 comprises an active surface 210a and an inactive surface 210b opposing the active surface 210a, wherein the chip 210 is mounted on the substrate 20 via a plurality of conductive bumps 22 formed on the active surface 210a, the protruding portion 270 is formed on the inactive surface 210b of the chip 210, and the heat sink 25 is disposed on the protruding portion 270 formed on the inactive surface 210b of the chip 210. Furthermore, a surface of the substrate 20 that is not attached to the chip 210 is implanted with a plurality of solder balls 28, thereby allowing the chip 210 to be electrically connected to an external device. For instance, the chip 210 is electrically connected to the substrate 20 via a plurality of conductive bumps 22 in a flip-chip manner. Moreover, the chip 210 has an underfill material 23 disposed thereunder, such that the conductive bumps 22 are encapsulated by the underfill material 23.

Additionally, the heat sink 25 comprises a flat portion 250 and a supporting portion 251 extended downward from a periphery of the flat portion 250. The heat sink 25 is secured on the substrate 20 through the supporting portion 251 by means of an adhesive. The protruding portion 270 is attached to the flat portion 250 by a heat conductive adhesive layer 26, such that the chip 210 is received in an accommodating space defined by the flat portion 250 and the supporting portion 251 of the heat sink 25. By such design and arrangement, the heat sink 25 can efficiently dissipate the heat generated by the chip 210 during operation.

Accordingly, a method for fabricating a semiconductor device and a chip structure of the present invention comprises cutting a wafer with an array of chips twice, wherein a plurality of grid-like grooves are formed between the chips during the first cutting and then the chips are separated by cutting the grooves between the chips during the second cutting. Moreover, the first cutting is wider than the second cutting, such that the chip structure can form the protruding portion on the inactive surface thereof. The ratio of the size of the protruding portion to the size of the inactive surface of the chip structure is between 0.5 and 0.8, and is preferably 0.67.

In addition, the chip structure is electrically connected to a substrate in a flip-chip manner, wherein the chip structure is attached to a heat sink via the protruding portion by employing the heat conductive adhesive layer. This thereby minimizes contact area between the chip structure and the heat sink so as to prevent warpage of the semiconductor device caused by thermal stress, as well as preventing delamination of the heat sink and cracking of conductive bumps. Accordingly, by implementing the present invention, finding suitable underfill materials for mounting chips of different sizes and different kinds on a substrate is no longer an issue, thereby saving fabrication time and fabrication cost dramatically.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A chip structure, comprising:
a body with an active surface and an inactive surface opposing the active surface; and
a protruding portion forming on the inactive surface wherein the protruding portion to inactive surface ratio in terms of size is between 0.5 and 0.8.

2. The chip structure of claim 1, wherein the protruding portion to inactive surface ratio in terms of size is preferably 0.67.

3. The chip structure of claim 1, further comprising an inverted T-shaped cross-section.

4. A semiconductor device, comprising:
a substrate;
a chip with an active surface and an inactive surface opposing the active surface, wherein the chip is electrically connected to the substrate via a plurality of conductive bumps formed on the active surface, and a protruding portion is formed on the inactive surface; and
a heat sink mounted on the protruding portion formed on the inactive surface of the chip, wherein the protruding portion to inactive surface ratio in terms of size is between 0.5 and 0.8.

5. The semiconductor device of claim 4, wherein the substrate comprises a surface not mounted with the chip, the surface being implanted with a plurality of solder balls.

6. The semiconductor device of claim 5, wherein the protruding portion to inactive surface ratio in terms of size is preferably 0.67.

7. The semiconductor device of claim 4, wherein the chip has an underfill material disposed thereunder to encapsulate the conductive bumps.

8. The semiconductor device of claim 4, wherein the heat sink comprises a flat portion and a supporting portion extended downward from a periphery of the flat portion.

9. The semiconductor device of claim 8, wherein the heat sink is secured on the substrate through the supporting portion, the protruding portion on the inactive surface of the chip is attached to the flat portion via a heat conductive adhesive layer, and the chip is received in an accommodating space defined by the flat portion and the supporting portion of the heat sink.

10. The semiconductor device of claim 4, wherein the chip comprises an inverted T-shaped cross-section.
